(19) United States
(12) Patent Application Publication
(10) Pub. No.: US 2026/0100997 A1
(43) Pub. Date: Apr. 9, 2026

(54) DISPLAY SCREEN AND WIRELESS COMMUNICATION DEVICE

(71) Applicant: Yungu (Gu’an) Technology Co., Ltd., Langfang (CN)

(72) Inventors: Huan-Chu HUANG, Taiwan (CN); Haijing SHEN, Langfang (CN); Xiaolong JI, Langfang (CN); Jie WU, Langfang (CN); Shuang CUI, Langfang (CN)

(73) Assignee: Yungu (Gu’an) Technology Co., Ltd., Langfang (CN)

(21) Appl. No.: 19/417,276

(22) Filed: Dec. 11, 2025

Related U.S. Application Data
(63) Continuation of application No. PCT/CN2023/134229, filed on Nov. 27, 2023.

(30) Foreign Application Priority Data
Jun. 13, 2023 (CN) 202310699559.7

(51) Int. Cl. H04M 1/02; G06F 1/18; H03C 7/02; H10H 29/45; H10H 29/49

(52) U.S. Cl. CPC H04M 1/0268; G06F 1/182; H03C 7/025; H10H 29/45; H10H 29/49

(57) ABSTRACT

Embodiments of the present application provide a display screen and a wireless communication device. The display screen includes: a substrate including a modulation circuit; a functional layer provided on the substrate and including a plurality of reflecting units, where the reflecting unit is configured to reflect a wireless signal and is connected to the modulation circuit, and the modulation circuit is configured to adjust at least one of an amplitude and a phase of an electrical signal on the reflecting unit; and a shielding layer provided on a side of the functional layer facing the substrate.

### CROSS-REFERENCE TO RELATED APPLICATIONS

The present application is a continuation of International Application No. PCT/CN 2023/134229, filed on Nov. 27, 2023, which claims priority to Chinese Patent Application No. 202310699559.7, filed on Jun. 13, 2023. All of the aforementioned patent applications are hereby incorporated by reference in their entireties.

### FIELD

The present application relates to the field of display devices, and in particular, to a display screen and a wireless communication device.

### BACKGROUND

Wireless communication devices (such as mobile phones and smart watches) are rapidly evolving in functionality, while there are increasingly high requirements for the appearance and wireless communication performance of the apparatuses on the market. How to improve the communication performance of display screens thus has become an urgent problem to be resolved.

### SUMMARY

Embodiments of the present application provide a display screen and a wireless communication device, which are intended to improve the wireless communication performance of the display screen.

An embodiment of a first aspect of the present application provides a display screen. The display screen includes: a substrate including a modulation circuit; a functional layer provided on the substrate and including a plurality of reflecting units, where the reflecting unit is configured to reflect a wireless signal and is connected to the modulation circuit, and the modulation circuit is configured to adjust at least one of an amplitude and a phase of an electrical signal on the reflecting unit; and a shielding layer provided on a side of the functional layer facing the substrate.

An embodiment of a second aspect of the present application provides a wireless communication device, including a display screen according to any one of the above embodiments of the first aspect.

In the display screen according to the embodiment of the present application, the display screen includes a substrate, a functional layer, and a shielding layer. A modulation circuit is provided on the substrate, a reflecting unit is provided in the functional layer, and the reflecting unit can reflect a wireless signal, thereby improving the wireless communication performance of the display screen. The modulation circuit can be configured to adjust an amplitude and/or a phase of an electrical signal on the reflecting unit, enabling the reflecting unit to reflect different wireless signals, thereby further enriching the wireless communication performance of the display screen. The shielding layer is provided on a side of the functional layer facing away from a display surface of the display screen, which can mitigate the impact of the transmission of a wireless signal into the display screen on the display screen, and can also improve the reflection effect of the reflecting unit. In addition, the present application enables the modulation circuit to be integrated within the substrate, which can reduce the distance between the reflecting unit and the modulation circuit, thereby improving the effect of signal transmission between the modulation circuit and the reflecting unit. Moreover, when the display screen is used for the wireless communication device, no external modulation circuit is required for the display screen within the wireless communication device, which can simplify the structure of the wireless communication device, thereby resulting in a smaller size.

### BRIEF DESCRIPTION OF THE DRAWINGS

FIG. 1 is a schematic diagram of a structure of a display screen according to an embodiment of a first aspect of the present application;

FIG. 2 is a schematic diagram of a circuit structure of a display screen according to an embodiment of a first aspect of the present application;

FIG. 3 is a partial cross-sectional view taken along line A-A in FIG. 1;

FIG. 4 is a schematic diagram of a structure of a display screen according to another embodiment of the first aspect of the present application;

FIG. 5 is a schematic diagram of a structure of a display screen according to yet another embodiment of the first aspect of the present application;

FIG. 6 is a schematic diagram of a structure of a display screen according to still another embodiment of the first aspect of the present application;

FIG. 7 is a schematic diagram of a circuit structure of a display screen according to another embodiment of the first aspect of the present application;

FIG. 8 is a schematic diagram of a structure of a display screen according to still yet another embodiment of the first aspect of the present application;

FIG. 9 is a partial cross-sectional view taken along line A-A in FIG. 1 in another example;

FIG. 10 is a schematic diagram of a structure of a display screen according to still yet another embodiment of the first aspect of the present application;

FIG. 11 is a schematic diagram of a structure of a display screen according to still yet another embodiment of the first aspect of the present application;

FIG. 12 is a schematic diagram of a circuit structure of a display screen according to yet another embodiment of the first aspect of the present application;

FIG. 13 is a schematic diagram of a circuit structure of a display screen according to still another embodiment of the first aspect of the present application;

FIG. 14 is a schematic diagram of a circuit structure of a display screen according to still yet another embodiment of the first aspect of the present application;

FIG. 15 is a schematic diagram of a structure of a display screen according to still yet another embodiment of the first aspect of the present application;

FIG. 16 is a schematic diagram of a structure of a display screen according to still yet another embodiment of the first aspect of the present application;

FIG. 17 is a schematic diagram of a structure of a display screen according to still yet another embodiment of the first aspect of the present application;

FIG. 18 is a schematic diagram of a structure of a display screen according to still yet another embodiment of the first aspect of the present application;

FIG. 19 is a schematic diagram of a structure of a display screen according to still yet another embodiment of the first aspect of the present application;

FIG. 20 is a schematic diagram of a structure of a display screen according to still yet another embodiment of the first aspect of the present application;

FIG. 21 is a schematic diagram of a structure of a display screen according to still yet another embodiment of the first aspect of the present application;

FIG. 22 is a partial cross-sectional view taken along line B-B in FIG. 21;

FIG. 23 is a schematic diagram of a structure of a display screen according to still yet another embodiment of the first aspect of the present application;

FIG. 24 is a schematic diagram of a structure of a display screen according to still yet another embodiment of the first aspect of the present application;

FIG. 25 is a schematic diagram of a structure of a display screen according to still yet another embodiment of the first aspect of the present application;

FIG. 26 is a partial cross-sectional view taken along line A-A in FIG. 1 in yet another example;

FIG. 27 is a schematic diagram of a structure of a wireless communication device according to an embodiment of a second aspect of the present application;

FIG. 28 is a schematic diagram of a structure of a wireless communication device according to another embodiment of the second aspect of the present application;

FIG. 29 is a cross-sectional view taken along line C-C in FIG. 28;

FIG. 30 is a schematic diagram of a structure of a wireless communication device according to still another embodiment of the second aspect of the present application;

FIG. 31 is a schematic diagram of a structure of a wireless communication device according to yet another embodiment of the second aspect of the present application;

FIG. 32 is a cross-sectional view taken along line C-C in FIG. 31 in an embodiment; and

FIG. 33 is a schematic diagram of a structure of a wireless communication device according to still yet another embodiment of the second aspect of the present application.

### DETAILED DESCRIPTION OF THE EMBODIMENTS

With the development of display technologies and wireless communication technologies, there are increasingly high requirements for the communication performance of wireless communication devices. Intelligent reflecting surface (IRS), as an important communication design that has currently attracted extensive attention and research investment, can change the direction of a reflected beam incident from a wireless signal source by regulating amplitudes and phases of electrical signals on a plurality of reflecting units on the intelligent reflecting surface (i.e., by changing electrical loads of the reflecting units), such as by directing the reflected beam, which is used as one reflected beam or split into a plurality of reflected beams, toward one or more communication targets, thereby facilitating a significant improvement in the wireless communication quality. The IRS may be installed on interior or exterior walls of a building.

The IRS is generally a structure of three layers, that is, a reflecting unit on the top layer, which is a conductor structure and is configured to reflect a wireless signal; a metal plate, such as a copper plate, below the reflecting unit, which is configured to shield and reflect a wireless signal; and a control circuit board provided on a side of the metal plate facing away from the reflecting unit, with a control circuit on the control circuit board being electrically connected to the reflecting unit and configured to regulate a signal amplitude and phase for each reflecting unit, to control the direction and number of reflected beams. However, since all the three layers in this structure are visually non-transparent to human eyes, the IRS is also visually non-transparent to human eyes.

In order to improve the communication performance of a display screen, the present application enables the IRS to be integrated onto the display screen. However, as mentioned above, current IRSs are primarily designed to be visually non-transparent to human eyes, which may obstruct a background (such as walls) on which they are installed, and compromise the original aesthetic design and consistency of the background, resulting in limited application scenarios and scope of the IRSs.

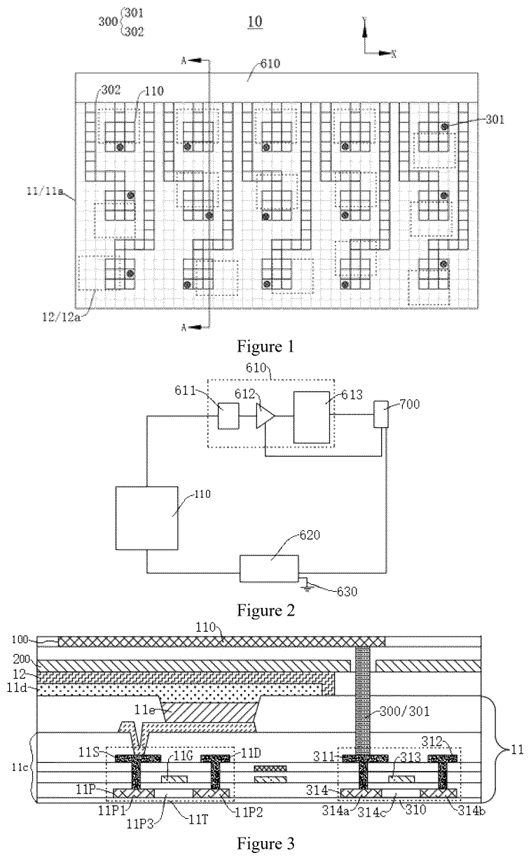

To resolve the above problem, the present application is provided. In order to better understand the present application, a display screen and a wireless communication device according to embodiments of the present application will be described below in detail with reference to FIG. 1 to FIG. 33.

Referring to FIG. 1 to FIG. 3, FIG. 1 is a schematic diagram of a structure of a display screen 10 according to an embodiment of the present application; FIG. 2 is a diagram of a circuit structure of a display screen 10 according to an embodiment of the present application; and FIG. 3 is a partial cross-sectional view taken along line A-A in FIG. 1.

As shown in FIG. 1 to FIG. 3, the display screen 10 according to an embodiment of a first aspect of the present application includes a substrate 11, a functional layer 100, and a shielding layer 200. The substrate 11 includes a modulation circuit 620. The functional layer 100 is provided on the substrate 11 and includes a plurality of reflecting units 110. The reflecting unit 110 is configured to reflect a wireless signal, and the reflecting unit 110 is connected to the modulation circuit 620. The modulation circuit 620 is configured to adjust at least one of an amplitude and a phase of an electrical signal on the reflecting unit 110. The shielding layer 200 is provided on a side of the functional layer 100 facing the substrate 11.

In one embodiment, the modulation circuit 620 is configured to adjust an electrical load of the reflecting unit 110.

In the display screen 10 according to the embodiment of the present application, the display screen 10 includes the substrate 11, the functional layer 100, and the shielding layer 200. The modulation circuit 620 is provided on the substrate 11, the reflecting unit 110 is provided in the functional layer 100, and the reflecting unit 110 can reflect the wireless signal, thereby improving the wireless communication performance of the display screen 10. The modulation circuit 620 can be configured to adjust the amplitude and/or phase of the electrical signal on the reflecting unit 110, enabling the reflecting unit 110 to reflect different wireless signals, thereby further enriching the wireless communication performance of the display screen 10. The shielding layer 200 is provided on a side of the functional layer 100 facing away from a display surface of the display screen 10, which can mitigate the impact of the transmission of a wireless signal into the display screen 10 on the display screen 10, and can also improve the reflection effect of the reflecting unit 110. In addition, the present application enables the modulation circuit 620 to be integrated within the substrate 11, which can reduce the distance between the reflecting unit 110 and the modulation circuit 620, thereby improving the effect of signal transmission between the modulation circuit 620 and the reflecting unit 110 (for example, reducing the signal path loss). Moreover, when the display screen 10 is used for the wireless communication device, no external modulation circuit 620 is required for the display screen 10 within the wireless communication device, which can simplify the structure of the wireless communication device, thereby resulting in a smaller size.

In one embodiment, the shielding layer 200 acts as a metal plate for the above-described IRS to shield and reflect the wireless signal.

In one embodiment, the reflecting unit 110 is further connected to a control circuit 610. In one embodiment, the display screen 10 includes a connection line 300. The connection line 300 includes a second connection line 302 and a first connection line 301. The second connection line 302 is configured to connect the reflecting unit 110 and the control circuit 610, and the first connection line 301 is configured to connect the reflecting unit 110 and the modulation circuit 620.

In one embodiment, the functional layer 100 may be provided in a grid-patterned metal wiring layer. The structure of a grid-patterned metal wiring is shown with gray lines, and the reflecting unit 110 and the second connection line 302 are shown with black lines in FIG. 1. In one embodiment, the grid-patterned metal wiring reused as the reflecting unit 110 and the second connection line 302 is insulated from metal wires at other positions, to avoid a short-circuited connection between adjacent reflecting units 110. In one embodiment, the control circuit 610 is shown in FIG. 1, in which the second connection line 302 is connected between the control circuit 610 and the reflecting unit 110. In other embodiments, the display screen 10 may not include the control circuit 610. For example, when the display screen 10 is used for the wireless communication device, the wireless communication device includes the control circuit 610.

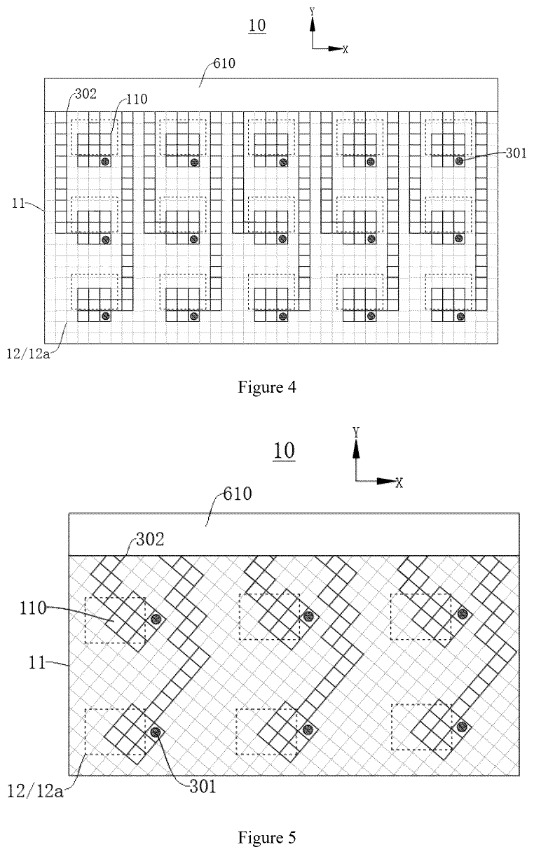

Referring to FIG. 1 to FIG. 4 together, FIG. 1 differs from FIG. 4 in the connection position between the second connection line 302 and the reflecting unit 110. The second connection line 302 may be connected to the reflecting unit 110 on any side in a peripheral direction. As shown in FIG. 1 and FIG. 3, the first connection line 301 may be connected to the reflecting unit 110 at different positions.

Referring to FIG. 1 to FIG. 5 together, FIG. 5 differs from FIG. 1 in the extension direction of metal traces in the grid-patterned metal wiring layer.

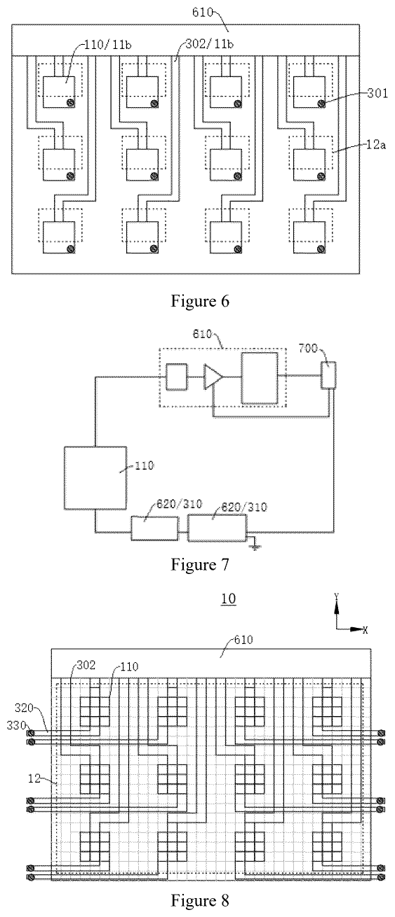

In some other embodiments, the reflecting unit 110 and/or the second connection line 302 may not be provided in the grid-patterned metal wiring layer. For example, as shown in FIG. 6, the reflecting unit 110 and/or the second connection line 302 is provided in a light-transmissive conductive layer.

In one embodiment, the control circuit 610 may be provided within the display screen 10, or when the display screen 10 is used for the wireless communication device, the control circuit 610 may also be provided within the wireless communication device. In one embodiment, the control circuit 610 and the modulation circuit 620 are further configured to be connected to a baseband 700. The baseband 700 is configured to control the state of the modulation circuit 620 and the control circuit 610. The baseband 700 may be provided within the display screen 10, or when the display screen 10 is used for the wireless communication device, the baseband 700 may also be provided within the wireless communication device. For example, the wireless communication device includes a circuit board. The baseband 700 and the control circuit 610 may be provided on the same circuit board, or the baseband 700 and the control circuit 610 may be separately provided on different circuit boards.

In one embodiment, the control circuit 610 includes a filter 611, an amplifier 612, and a downconverter 613. The filter 611, the amplifier 612, and the downconverter 613 are sequentially connected between the reflecting unit 110 and the baseband 700. In one embodiment, the baseband 700 and the amplifier 612 are electrically connected to each other and the baseband 700 can control switching on and switching off of the control circuit 610 through the amplifier 612. In one embodiment, the amplifier 612 is a tunable low noise amplifier.

The modulation circuit 620 may be provided in various ways. For example, the modulation circuit 620 includes at least one of a variable resistor, a variable capacitor, and a variable inductor, and by adjusting a resistance value of the variable resistor, a capacitance of the variable capacitor, and an inductance value of the variable inductor, the amplitude and/or phase of the electrical signal on the reflecting unit 110 can be adjusted.

In some other embodiments, still referring to FIG. 2 and FIG. 3, the modulation circuit 620 includes a first transistor 310. The first transistor 310 includes a first source 311, a first drain 312, a first gate 313, and a first semiconductor portion 314. One of the first source 311 and the first drain 312 is connected to the reflecting unit 110, and the other is connected to a first power signal line 630 through the first semiconductor portion 314. In the present application, description is given by way of example in which the first source 311 is connected to the reflecting unit 110, and the first drain 312 is connected to the first power signal line 630. In other embodiments, it is also possible that the first source 311 is connected to the first power signal line 630, and the first drain 312 is connected to the reflecting unit 110.

In these embodiments, the reflecting unit 110 is electrically connected to the first power signal line 630 through the first source 311, the first semiconductor portion 314, and the first drain 312, and by controlling the first gate 313, the resistance and/or inductance of the first semiconductor portion 314 can be controlled to achieve the purpose of adjusting the amplitude and/or phase of the electrical signal on the reflecting unit 110.

In one embodiment, the first power signal line 630 is a low-level power signal line or a negative voltage power signal line.

In one embodiment, the other of the first source 311 and the first drain 312 may also be connected to a second signal line. For example, when the first source 311 is connected to the reflecting unit 110, the first drain 312 may also be connected to the second signal line; or when the first drain 312 is connected to the reflecting unit 110, the first source 311 may also be connected to the second signal line. That is, the other is connected to the first power signal line 630 and the second signal line.

In these embodiments, there is a voltage difference between the second signal line and the reflecting unit 110, and also between the first power signal line 630 and the reflecting unit 110, and by adjusting the potential of the second signal line, the direction of a current between the first source 311 and the first drain 312 in the first transistor 310 can be controlled, thereby adjusting the amplitude and/or phase of the electrical signal on the reflecting unit 110.

In some embodiments, as shown in FIG. 3, the display screen 10 further includes a light-emitting layer. The light-emitting layer includes a light-emitting unit 11e, and the substrate 11 includes a drive circuit configured to drive the light-emitting unit 11e to emit light. The modulation circuit 620 is provided on an array substrate 11c.

In these embodiments, the substrate 11 includes the drive circuit configured to drive the light-emitting unit 11e to emit light, and therefore, the substrate 11 includes the array substrate 11c; and the modulation circuit 620 is provided within the array substrate 11c including the drive circuit, and the modulation circuit 620 can be prepared and formed in synchronization with at least part of the structure in the drive circuit, thereby simplifying the preparation of the display screen 10.

In one embodiment, the substrate 11 further includes a base substrate, and the array substrate 11c is provided on the base substrate.

In some embodiments, as shown in FIG. 3, the drive circuit includes a second transistor 11T. The second transistor 11T includes a second semiconductor portion 11P, a second gate 11G, a second source 11S, and a second drain 11D. In one embodiment, the drive circuit may be any one of a 2T1C circuit, a 7T1C circuit, a 7T2C circuit, a 9T1C circuit, or a 14T2C circuit. As used herein, the term “2T1C circuit” refers to a pixel circuit including two thin film transistors (T) and one capacitor (C), and other terms including “7T1C circuit”, “7T2C circuit”, “9T1C circuit” shall be construed accordingly.

In one embodiment, the second semiconductor portion 11P includes a second source region 11P1, a second drain region 11P2, and a second channel region 11P3 located between the second source region 11P1 and the second drain region 11P2.

In one embodiment, the first semiconductor portion 314 and the second semiconductor portion 11P are provided in the same layer, and the first semiconductor portion 314 and the second semiconductor portion 11P can be prepared synchronously, thereby simplifying the preparation process of the display screen 10.

In one embodiment, the first gate 313 and the second gate 11G are provided in the same layer, and the first gate 313 and the second gate 11G can be prepared synchronously, thereby simplifying the preparation process of the display screen 10.

In one embodiment, the first source 311 and the second source 11S are provided in the same layer, and the first drain 312 and the second drain 11D are provided in the same layer, and the first source 311 and the second source 11S can be prepared synchronously, and the first drain 312 and the second drain 11D can be prepared synchronously, thereby simplifying the preparation process of the display screen 10.

In one embodiment, the first semiconductor portion 314 includes a first source region 314a and a first drain region 314b, the first source 311 is electrically connected to the first source region 314a, and the first drain 312 is electrically connected to the first drain region 314b. In one embodiment, the first semiconductor portion 314 further includes a first channel region 314c, and the first channel region 314c is located between the first source region 314a and the first drain region 314b. In one embodiment, a projection of the first channel region 314c in a thickness direction of the display screen 10 is within a projection of the first gate 313 in the thickness direction.

In some embodiments, the first drain 312 is connected to the reflecting unit 110, and the first semiconductor portion 314 includes a first source region 314a. The first source region 314a is connected to the first power signal line 630, and the first source region 314a is connected to the first source 311.

In these embodiments, the first source region 314a is connected to the first source 311 and the first power signal line 630, and by controlling voltages on the first power signal line 630 and the first source 311, the direction of current flow between the first source region 314a and the first drain region 314b can be controlled.

In some other embodiments, it is also possible that the first source 311 is connected to the reflecting unit 110, and the first drain region 314b is connected to the first power signal line 630, and by controlling voltages on the first power signal line 630 and the first drain 312, the direction of current flow between the first source region 314a and the first drain region 314b can be controlled.

Different numbers of first transistors 310 may be provided. One first transistor 310 may be provided, and the first transistor 310 is connected in series between the reflecting unit 110 and the first power signal line 630.

In some other embodiments, as shown in FIG. 3 and FIG. 7, a plurality of first transistors 310 may also be provided, the plurality of first transistors 310 are sequentially connected in series with each other to form a series circuit, and the first transistor 310 at a lead end on the series circuit is connected to the reflecting unit 110, and the first transistor 310 at a tail end on the series circuit is connected to the first power signal line 630.

In the above embodiment, the term “lead end” refers to a position of the first transistor 310 in the series circuit that has the shortest current path length relative to the reflecting unit 110, and the term “tail end” refers to a position of the first transistor 310 in the series circuit that has the longest current path length relative to the reflecting unit 110. A current path is a flow path of a current when the current passes through the reflecting unit 110 and the first power signal line 630 or the series circuit.

In these embodiments, the plurality of first transistors 310 are connected in series with each other to form the series circuit, and the first transistor 310 at the lead end on the series circuit is connected to the reflecting unit 110, and the first transistor 310 at the tail end on the series circuit is connected to the first power signal line 630, that is, two first transistors 310 located at two ends of the series circuit are connected to the reflecting unit 110 and the first power signal line 630, respectively. By providing the plurality of first transistors 310, the adjustment range of the modulation circuit 620 can be widened.

In one embodiment, the first transistor 310 at the lead end is connected to a first reflecting unit, and the first transistor 310 at the tail end is connected to the first power signal line 630. When the first drain 312 of the first transistor 310 at the lead end is connected to the reflecting unit 110, the first source 311 of the first transistor 310 at the tail end is connected to the first power signal line 630, or when the first source 311 of the first transistor 310 at the lead end is connected to the reflecting unit 110, the first drain 312 of the first transistor 310 at the tail end is connected to the first power signal line 630.

In one embodiment, when a plurality of first transistors 310 are provided, and the plurality of first transistors 310 are connected in series with each other to form a series circuit, the plurality of first transistors 310 may have the same or different characteristics. For example, first channel regions 314c of the plurality of first transistors 310 may have different sizes from each other, and/or the first channel regions 314c of the plurality of first transistors 310 may have different resistance values from each other. As such, first semiconductor portions 314 of different first transistors 310 can be adjusted, thereby achieving different adjustment requirements.

In still some embodiments, when a plurality of first transistors 310 are provided, the plurality of first transistors 310 may also be connected in parallel to each other, thereby improving the adjustment accuracy of the modulation circuit 620.

In some embodiments, as shown in FIG. 3, as described above, the display screen 10 further includes the light-emitting layer and an encapsulation layer 12. The light-emitting layer is located on a side of the functional layer 100 facing the substrate 11, and includes a plurality of light-emitting units 11e spaced apart from each other. The encapsulation layer 12 is located on a side of the light-emitting layer facing away from the substrate 11, and is configured to encapsulate the light-emitting units 11e. As described above, the display screen 10 further includes the connection line 300. One end of the connection line 300 is connected to the reflecting unit 110, and the other end of the connection line 300 is connected to the modulation circuit 620, and the modulation circuit 620 is connected to the reflecting unit 110 through the connection line 300, or the other end of the connection line 300 is configured to be connected to the control circuit 610, and the control circuit 610 can change the electrical load of the reflecting unit 110 through the connection line 300. At least part of an orthographic projection of the connection line 300 on the substrate 11 is outside an orthographic projection of the encapsulation layer 12 on the substrate 11.

For example, when the connection line 300 is the second connection line 302, the connection line 300 connects the reflecting unit 110 and the control circuit 610, or when the connection line 300 is the first connection line 301, the connection line 300 connects the reflecting unit 110 and the modulation circuit 620.

In these embodiments, the display screen 10 further includes the light-emitting layer and the encapsulation layer 12, the light-emitting units 11e in the light-emitting layer are configured to implement the light emission for display of the display screen 10, and the encapsulation layer 12 is configured to encapsulate the light-emitting units 11e to alleviate the problem that a light-emitting material in the light-emitting unit 11e is subjected to moisture and oxygen intrusion that affects its light-emitting effect. The connection line 300 is configured to connect the modulation circuit 620 and the reflecting unit 110, or the connection line 300 is configured to connect the control circuit 610 and the reflecting unit 110, and at least part of the orthographic projection of the connection line 300 on the substrate 11 is outside the orthographic projection of the encapsulation layer 12 on the substrate 11, which can mitigate the impact of the connection line 300 on the encapsulation effect of the encapsulation layer 12.

In one embodiment, the reflecting unit 110 is located on a side of the encapsulation layer 12 facing away from the substrate 11. As such, the impact of the reflecting unit 110 on the encapsulation effect of the encapsulation layer 12 can be mitigated.

In one embodiment, as described above, the connection line 300 includes the first connection line 301 and the second connection line 302. The first connection line 301 is configured to connect the reflecting unit 110 and the modulation circuit 620, and the second connection line 302 is configured to connect the reflecting unit 110 and the control circuit 610. At least part of an orthographic projection of the first connection line 301 on the substrate 11 and at least part of an orthographic projection of the second connection line 302 on the substrate are outside the orthographic projection of the encapsulation layer 12 on the substrate 11.

In these embodiments, the first connection line 301 is configured to connect the reflecting unit 110 and the modulation circuit 620, the second connection line 302 is configured to connect the reflecting unit 110 and the control circuit 610, and the at least part of the projection of the first connection line 301 and the at least part of the projection of the second connection line 302 are both outside the projection of the encapsulation layer 12, which can mitigate the impact of the first connection line 301 and the second connection line 302 on the encapsulation effect of the encapsulation layer 12.

In one embodiment, at least part of the first connection line 301 and the second connection line 302 may be reused. For example, one end of the connection line 300 is connected to the reflecting unit 110, and the other end of the connection line 300 is divided into a first sub-line configured to be connected to the modulation circuit 620 and a second sub-line configured to be connected to the control circuit 610, and the reflecting unit 110 can be connected to both the modulation circuit 620 and the control circuit 610 through the connection line 300.

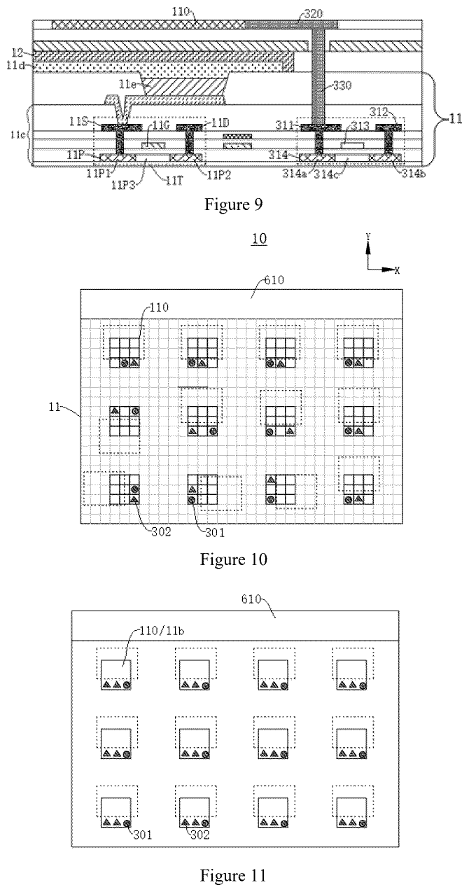

In some embodiments, as shown in FIG. 8 and FIG. 9, the encapsulation layer 12 may be a full-surface encapsulation structure. For example, orthographic projections of the plurality of light-emitting units 11e on the substrate 11 are within the orthographic projection of the encapsulation layer 12 on the substrate 11. The connection line 300 includes a first sub-section 320 and a second sub-section 330. The first sub-section 320 connects the reflecting unit 110 and the second sub-section 330. The second sub-section 330 extends in the thickness direction and connects the first sub-section 320 to the modulation circuit 620 and/or the control circuit 610. An orthographic projection of the second sub-section 330 on the substrate 11 is outside the orthographic projection of the encapsulation layer 12 on the substrate 11. FIG. 8 shows the position of the encapsulation layer 12 in dashed lines, which do not constitute a limitation on the structure of the display screen 10 according to the embodiments of the present application.

In these embodiments, encapsulation layer 12 is a full-surface encapsulation structure. The orthographic projections of the plurality of light-emitting units 11e on the substrate 11 are within the orthographic projection of the same encapsulation layer 12 on substrate 11, and the plurality of light-emitting units 11e are encapsulated by the same encapsulation layer 12. The first sub-section 320 of the connection line 300 connects the reflecting unit 110 and the second sub-section 330, and the second sub-section 330 of the connection line extends in the thickness direction to connect the first sub-section 320 to the modulation circuit 620 and/or the control circuit 610, and the orthographic projection of the second sub-section 330 on the substrate 11 is outside the orthographic projection of the encapsulation layer 12 on the substrate 11, which can mitigate the impact of the second sub-section 330 on the encapsulation effect, and prevent the second sub-section 330 from penetrating the encapsulation layer 12 in the thickness direction.

In one embodiment, the first sub-section 320 and the reflecting unit 110 are provided in the same layer to reduce the connection distance between the first sub-section 320 and the reflecting unit 110.

In one embodiment, in other embodiments, the first sub-section 320 and the reflecting unit 110 may also be provided in different layers. The first sub-section 320 and the reflecting unit 110 are connected to each other through a via hole, and the first sub-section 320 is located on a side of the encapsulation layer 12 facing the reflecting unit 110, to prevent the first sub-section 320 from penetrating the encapsulation layer 12. For example, the first sub-section 320 is located between the encapsulation layer 12 and the reflecting unit 110, or the first sub-section 320 is located on a side of the reflecting unit 110 facing away from the encapsulation layer 12.

In some other embodiments, still referring to FIG. 1 and FIG. 3, the encapsulation layer 12 includes a plurality of encapsulation portions 12a spaced-apart from each other, and an orthographic projection of each light-emitting unit 11e on the substrate 11 is within an orthographic projection of each encapsulation portion 12a on the substrate 11. The reflecting unit 110 includes a first portion and a second portion. An orthographic projection of the first portion on the substrate 11 is within the orthographic projection of the encapsulation portion 12a on the substrate 11, and an orthographic projection of the second portion on the substrate 11 is outside the orthographic projection of the encapsulation portion 12a on the substrate 11. The connection line 300 extends in the thickness direction of the display screen 10 and connects the second portion to the modulation circuit 620 and/or the control circuit 610. The position of each encapsulation portion 12a is shown in dashed lines in FIG. 1.

In these embodiments, the encapsulation layer 12 includes the plurality of encapsulation portions 12a provided independently of one another, and each light-emitting unit 11e is encapsulated by each encapsulation portion 12a. The reflecting unit 110 includes the first portion and the second portion, the first portion overlaps the encapsulation portion 12a, and the second portion does not overlap the encapsulation portion 12a. The connection line 300 connects the second portion to the modulation circuit 620 and/or the control circuit 610, which can prevent the connection line 300 from affecting the encapsulation effect of the encapsulation portion 12a.

In one embodiment, as described above, the connection line 300 includes the second connection line 302 and the first connection line 301, and it is shown in FIG. 1 and FIG. 3 that the first connection line 301 extends in the thickness direction of the display screen 10. As shown in FIG. 10, orthographic projections of the second connection line 302 and the first connection line 301 on the substrate 11 are both outside the orthographic projection of the encapsulation portion 12a on the substrate 11, that is, at least part of the second connection line 302 extends in the thickness direction and connects the reflecting unit 110 and the control circuit 610.

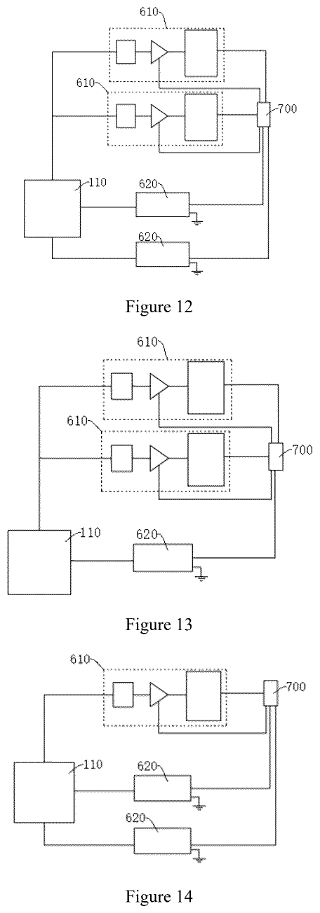

In one embodiment, as shown in FIG. 11 and FIG. 12, when the same reflecting unit 110 is connected to two or more control circuits 610, the same reflecting unit 110 has two or more second connection lines 302 connected thereto, and orthographic projections of the two or more second connection lines 302 on the substrate 11 are all outside the orthographic projection of the encapsulation portion 12a on the substrate 11.

In one embodiment, as shown in FIG. 12 to FIG. 14, the same reflecting unit 110 may also be connected to two or more modulation circuits 620. The same reflecting unit 110 may also be connected to two or more modulation circuits 620 and two or more control circuits 610.

In some other embodiments, when the reflecting unit 110 completely overlaps the encapsulation portion 12a, or when the orthographic projection of the reflecting unit 110 on the substrate 11 is within the orthographic projection of the encapsulation portion 12a on the substrate 11, the connection line 300 may include the first sub-section 320 and the second sub-section 330 described above, the first sub-section 320 connects the reflecting unit 110 and the second sub-section 330, and the second sub-section 330 extends in the thickness direction and connects the first sub-section 320 to the modulation circuit 620 and/or the control circuit 610. That is, when the reflecting unit 110 completely overlaps the encapsulation portion 12a, and the connection line 300 may damage the encapsulation portion 12a when extending directly in the thickness direction, the connection line 300 may include the first sub-section 320 and the second sub-section 330, and the first sub-section 320 guides the connection position of the connection line 300 out of the encapsulation portion 12a, and then the second sub-section 330 extends in the thickness direction to connect the first sub-section 320 to the modulation circuit 620 and/or the control circuit 610. This can also mitigate the impact of the connection line 300 on the encapsulation effect of the encapsulation portion 12a.

In one embodiment, the functional layer 100 and the shielding layer 200 are transparent structural layers. For example, an overall light transmittance of the functional layer 100 and the shielding layer 200 is greater than 50%. In one embodiment, a light transmittance of the functional layer 100 is greater than 60%, 70%, 80%, or even 90%. In one embodiment, a light transmittance of the shielding layer 200 is greater than 60%, 70%, 80%, or even 90%.

In the display screen 10 according to the embodiments of the present application, the functional layer 100 includes the reflecting unit 110, and the reflecting unit 110 can reflect the wireless signal, for example, the reflecting unit 110 can reflect the wireless signal to a communication target, to improve the wireless communication quality of the display screen 10. The shielding layer 200 is provided on the side of the functional layer 100 facing away from the display surface of the display screen 10, and the shielding layer 200 can shield the wireless signal to enable the wireless signal to be reflected at the functional layer 100, and can also improve the situation of the entry of the wireless signal into the display screen 10 that affects the operation of other parts and components of the display screen 10. The overall light transmittance of the functional layer 100 and the shielding layer 200 is greater than 50%, which can reduce the impact of the functional layer 100 and the shielding layer 200 on the display effect of the display screen 10. Therefore, the embodiments of the present application can effectively improve the wireless communication performance of the display screen 10 by providing the functional layer 100 and the shielding layer 200 with high light transmittance in the display screen 10.

In one embodiment, the display screen 10 may be an organic light-emitting diode display screen 10, a liquid crystal display screen 10, or a microlight-emitting diode display screen 10.

In one embodiment, each reflecting unit 110 is connected to at least one modulation circuit 620, and different reflecting units 110 are connected to different modulation circuits 620, enabling separate adjustment of amplitudes and/or phases of electrical signals on the respective reflecting units 110 through the respective modulation circuits 620.

In one embodiment, each reflecting unit 110 is connected to at least one control circuit 610, and different reflecting units 110 are connected to different control circuits 610, enabling separate control of electrical loads of the respective reflecting units 110 through the respective control circuits 610.

In one embodiment, orthographic projections of two or more reflecting units 110 on the substrate 11 are within an orthographic projection of the shielding layer 200 on the substrate 11.

Different numbers of functional layers 100 may be provided. For example, as shown in FIG. 1, one functional layer 100 is provided, and two or more reflecting units 110 distributed in an array are provided within the functional layer 100. In one embodiment, one shielding layer 200 is provided.

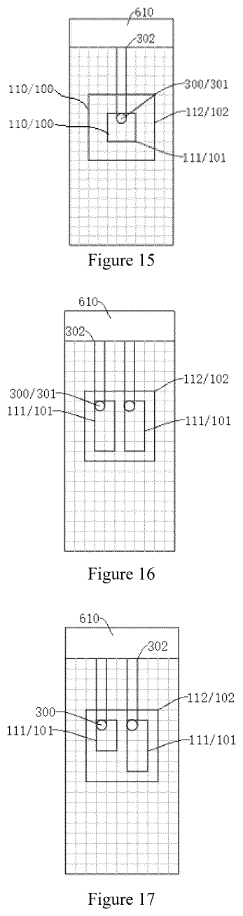

In some other embodiments, as shown in FIG. 15, FIG. 15 is a partial enlarged view of a display screen 10. Two or more functional layers 100 are provided, and at least two reflecting units 110 located in different functional layers 100 have different areas of orthographic projections on the substrate 11. In one embodiment, FIG. 15 shows, on a top view, that two reflecting units 110 nested with each other are located in two different functional layers 100. Only one group of at least partially overlapping reflecting units 110 is shown in FIG. 15. In one embodiment, a plurality of groups of at least partially overlapping reflecting units 110 may be provided.

In these embodiments, two or more functional layers 100 are provided, and reflecting units 110 of different sizes are provided in different functional layers 100, and the reflecting units 110 of different sizes can reflect wireless signals in different frequency bands, thereby further improving the wireless communication performance of the display screen 10.

In one embodiment, two or more reflecting units 110 in the same functional layer 100 have the same area of orthographic projections on the substrate 11, that is, the two or more reflecting units 110 in the same functional layer 100 have the same size, and the two or more reflecting units 110 in the same functional layer 100 can reflect wireless signals in the same frequency band, thereby enhancing the ability to reflect the wireless signals in the same frequency band.

In some embodiments, still referring to FIG. 15, when two or more functional layers 100 are provided, the two or more functional layers 100 include a first functional layer 101 and a second functional layer 102, that is, one of the two or more functional layers 100 is the first functional layer 101, and the other is the second functional layer 102. The reflecting unit 110 includes a first reflecting unit 111 located in the first functional layer 101 and a second reflecting unit 112 located in the second functional layer 102. The first functional layer 101 is located on a side of the second functional layer 102 facing the display surface of the display screen 10, and an area of an orthographic projection of the first reflecting unit 111 on the substrate 11 is less than an area of an orthographic projection of the second reflecting unit 112 on the substrate 11.

In these embodiments, the first reflecting unit 111 is located on a side of the second reflecting unit 112 facing the display surface of the display screen 10, and a size of the first reflecting unit 111 is less than a size of the second reflecting unit 112. As such, at least part of the second reflecting unit 112 is not shielded by the first reflecting unit 111, and the second reflecting unit 112 can also reflect a wireless signal. In addition, since the size of the first reflecting unit 111 is different from the size of the second reflecting unit 112, wireless signals in a plurality of frequency bands can be reflected, and the display screen 10 is able to regulate reflected signals for wireless signals in different frequency bands.

In one embodiment, an orthographic projection of each first reflecting unit 111 on the substrate 11 at least partially overlaps an orthographic projection of each second reflecting unit 112 on the substrate 11. As such, the overall distribution area of the two or more reflecting units 110 can be reduced. The orthographic projection of each first reflecting unit 111 on the substrate 11 at least partially overlapping the orthographic projection of each second reflecting unit 112 on the substrate 11 includes: first reflecting units 111 being provided in a one-to-one correspondence with second reflecting units 112, and the orthographic projection of each first reflecting unit 111 on the substrate 11 at least partially overlapping the orthographic projection of each second reflecting unit 112 on the substrate 11; or two or more first reflecting units 111 being provided corresponding to the same second reflecting unit 112, or the same first reflecting unit 111 being provided corresponding to two or more second reflecting units 112, provided that the orthographic projection of each first reflecting unit 111 on the substrate 11 can at least partially overlap the orthographic projection of at least one second reflecting unit 112 on the substrate 11, or the orthographic projection of each second reflecting unit 112 on the substrate 11 can at least partially overlap the orthographic projection of at least one first reflecting unit 111 on the substrate 11.

In one embodiment, as shown in FIG. 15, at least part of the connection line 300 is provided in an overlapping area between the first reflecting unit 111 and the second reflecting unit 112 and is connected to the first reflecting unit 111 and the second reflecting unit 112.

In these embodiments, providing the at least part of the connection line 300 in the overlapping area between the first reflecting unit 111 and the second reflecting unit 112 and enabling the connection line 300 to extend in the thickness direction of the display screen 10 to be connected to both the first reflecting unit 111 and the second reflecting unit 112 can simplify the structure of the connection line 300.

In one embodiment, an orthographic projection of the overlapping area on the substrate 11 is outside the orthographic projection of the encapsulation portion 12a on the substrate 11, and the connection line 300 can be located outside the orthographic projection of the encapsulation portion 12a on the substrate 11.

In one embodiment, as shown in FIG. 15, first reflecting units 111 may be provided in a one-to-one correspondence with second reflecting units 112. In one embodiment, as shown in FIG. 16, since the size of the first reflecting unit 111 is less than the size of the second reflecting unit 112, two or more first reflecting units 111 may be provided corresponding to the same second reflecting unit 112.

In some embodiments, as shown in FIG. 16, two or more first reflecting units 111 are provided corresponding to the same second reflecting unit 112, and in the corresponding second reflecting unit 112 and two or more first reflecting units 111, the orthographic projections of the two or more first reflecting units 111 on the substrate 11 are within the orthographic projection of the same second reflecting unit 112 on the substrate 11. Only one second reflecting unit 112 is shown in FIG. 5. In one embodiment, a plurality of second reflecting units 112 may be provided. The plurality of second reflecting units 112 are spaced apart from each other, and two or more first reflecting units 111 are provided on a side of each second reflecting unit 112 facing the display surface of the display screen 10.

In these embodiments, since the size of the first reflecting unit 111 is relatively small, providing the two or more first reflecting units 111 corresponding to the same second reflecting unit 112 can increase the number of first reflecting units 111 that can be provided, thereby improving the wireless communication performance of the first functional layer 101. The orthographic projections of the two or more first reflecting units 111 on the substrate 11 are within the orthographic projection of the same second reflecting unit 112 on the substrate 11, which makes the arrangement of the first reflecting units 111 and the second reflecting unit 112 more regular, thereby facilitating preparation and formation.

In one embodiment, as shown in FIG. 17, in the corresponding second reflecting unit 112 and two or more first reflecting units 111, the two or more first reflecting units 111 have different areas of projections on the substrate 11, and the two or more first reflecting units 111 corresponding to the same second reflecting unit 112 can reflect wireless signals in different frequency bands, thereby further improving the wireless communication performance of the display screen 10.

In some other embodiments, as shown in FIG. 16, in the corresponding second reflecting unit 112 and two or more first reflecting units 111, the two or more first reflecting units 111 may also have the same area of orthographic projections on the substrate 11.

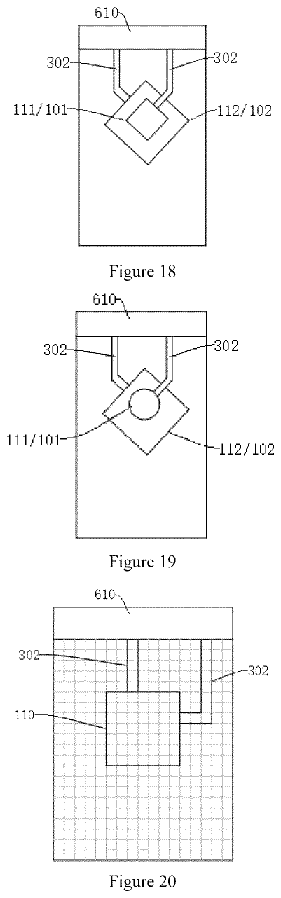

In one embodiment, as shown in FIG. 18 and FIG. 19, the orthographic projection of the first reflecting unit 111 on the substrate 11 and the orthographic projection of the second reflecting unit 112 on the substrate 11 may have the same or different shapes. For example, the orthographic projection of the second reflecting unit 112 on the substrate 11 has a rectangular shape, and the orthographic projection of the first reflecting unit 111 on the substrate 11 may have a rectangular or circular shape.

In one embodiment, when the same reflecting unit 110 is connected to two or more control circuits 610, as shown in FIG. 20, the same reflecting unit 110 has two or more second connection lines 302 connected thereto, and the reflecting unit 110 is connected to the respective control circuits 610 through the respective second connection lines 302. When the same reflecting unit 110 has two or more second connection lines 302 connected thereto, the two or more second connection lines 302 are spaced apart from each other on the same reflecting unit 110, to alleviate interference between the two or more second connection lines 302.

In one embodiment, when the same reflecting unit 110 is connected to two or more modulation circuits 620, the same reflecting unit 110 has two or more first connection lines 301 connected thereto, and the reflecting unit 110 is connected to the respective modulation circuits 620 through the respective first connection lines 301. When the same reflecting unit 110 has two or more first connection lines 301 connected thereto, the two or more first connection lines 301 are spaced apart from each other on the same reflecting unit 110, to alleviate interference between the two or more first connection lines 301.

In some embodiments, as shown in FIG. 1, the display screen 10 further includes a signal line layer 11a. The reflecting unit 110 and the second connection line 302 may be provided in the same layer and both located in the signal line layer 11a, to simplify the structure of the display screen 10.

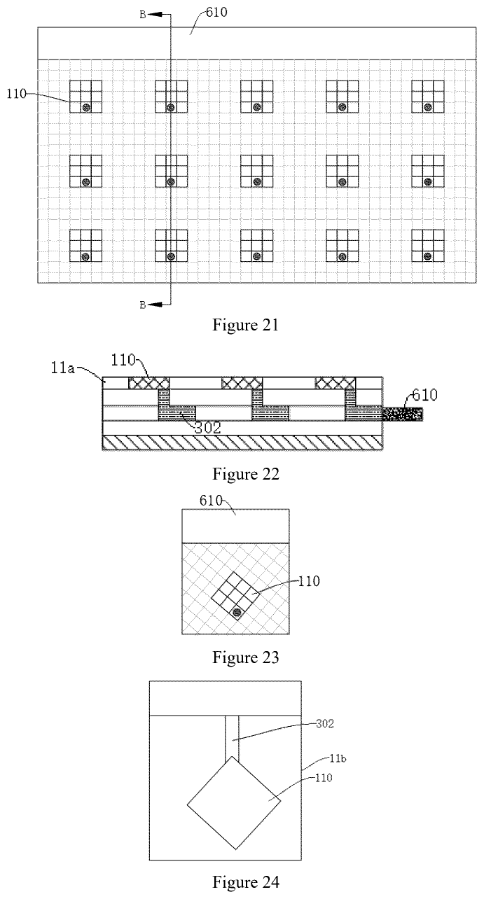

As shown in FIG. 21 to FIG. 23, the reflecting unit 110 is provided in the signal line layer 11a, while the second connection line 302 is provided in another conductive layer. Providing the reflecting unit 110 and the second connection line 302 in different layers facilitates flexible arrangement of the second connection line 302 in the other conductive layer. In one embodiment, the second connection line 302 is provided in the signal line layer 11a, while the reflecting unit 110 is provided in another conductive layer. This facilitates flexible arrangement of the second connection line 302 in the signal line layer 11a and flexible arrangement of the reflecting unit 110 in the other conductive layer, enabling the arrangement of the reflecting unit 110 and the arrangement of the second connection line 302 not to interfere with each other. In FIG. 21 and FIG. 23, since the reflecting unit 110 and the second connection line 302 are provided in different layers, the reflecting unit 110 can be observed while the second connection line 302 cannot be observed from the top view.

In one embodiment, the second connection line 302 may be provided in a conductive layer on a side of the functional layer 100 facing away from the shielding layer 200. For example, the second connection line 302 is provided in the signal line layer 11a, and the signal line layer 11a may be located on the side of the functional layer 100 facing away from the shielding layer 200. In one embodiment, as shown in FIG. 22, the second connection line 302 may be provided in a conductive layer between the functional layer 100 and the shielding layer 200. In one embodiment, the second connection line 302 is provided in the signal line layer 11a, and the signal line layer 11a may be located between the functional layer 100 and the shielding layer 200.

The signal line layer 11a may be provided in various ways. For example, as shown in FIG. 1, the signal line layer 11a includes a grid-patterned metal wiring, and at least part of the metal wiring is reused as the reflecting unit 110 and/or the connection line 300. The grid-patterned metal wiring includes a first signal line extending in a first direction X (a gray signal line extending in the first direction X in FIG. 1) and a second signal line extending in a second direction Y (a gray signal line extending in the second direction Y in FIG. 1). A plurality of first signal lines and a plurality of second signal lines intersect to form a grid pattern.

As described above, when part of the metal wiring is reused as the reflecting unit 110 and/or the connection line 300, the part of the metal wiring is insulated from metal wirings at other positions, to avoid a short-circuited connection between adjacent reflecting units 110 and/or connection lines 300.

In one embodiment, as shown in FIG. 5, an extension direction of the grid-patterned metal wiring intersects a length direction of the display screen 10. The extension direction of the grid-patterned metal wiring may be an extension direction of the first signal line, or may be an extension direction of the second signal line. The display screen 10 includes a first side edge and a second side edge, and two first sides and two second sides are alternately connected to enclose the display screen 10. A length of the first side edge is greater than a length of the second side edge, and an extension direction of the first side edge may be the length direction of the display screen 10. The extension direction of the grid-patterned metal wiring intersecting the length direction of the display screen 10 means the extension direction of the first signal line and/or the second signal line intersecting the extension direction of the first side edge, which can reduce the impact of the grid-patterned metal wiring on the display effect of the display screen 10.

In some other embodiments, as shown in FIG. 6, the display screen 10 further includes a light-transmissive conductive layer 11b. A material of the light-transmissive conductive layer 11b includes a light-transmissive conductive material such as indium tin oxide, to improve the light transmittance of the light-transmissive conductive layer 11b. The light-transmissive conductive layer 11b has the characteristics of high light transmittance and conducting electricity.

In one embodiment, at least one of the reflecting unit 110, the connection line 300, and the shielding layer 200 is provided in the light-transmissive conductive layer 11b, to improve the light transmission performance of the reflecting unit 110 and the shielding layer 200, and reduce the impact of the reflecting unit 110 and the shielding layer 200 on the display effect of the display screen 10.

In one embodiment, the light-transmissive conductive layer 11b includes a first conductive layer (not shown in the figure) and a second conductive layer (not shown in the figure) that are stacked. At least one of the reflecting unit 110 and the connection line 300 is provided in the first conductive layer, and the shielding layer 200 is provided in the second conductive layer. In these embodiments, the connection line 300 and the shielding layer 200 are both provided in the light-transmissive conductive layer 11b, and are located in different conductive layers, which can alleviate interference between the arrangement of the connection line 300 and the arrangement of the shielding layer 200, and can also ensure the light transmittance of the reflecting unit 110 and the shielding layer 200.

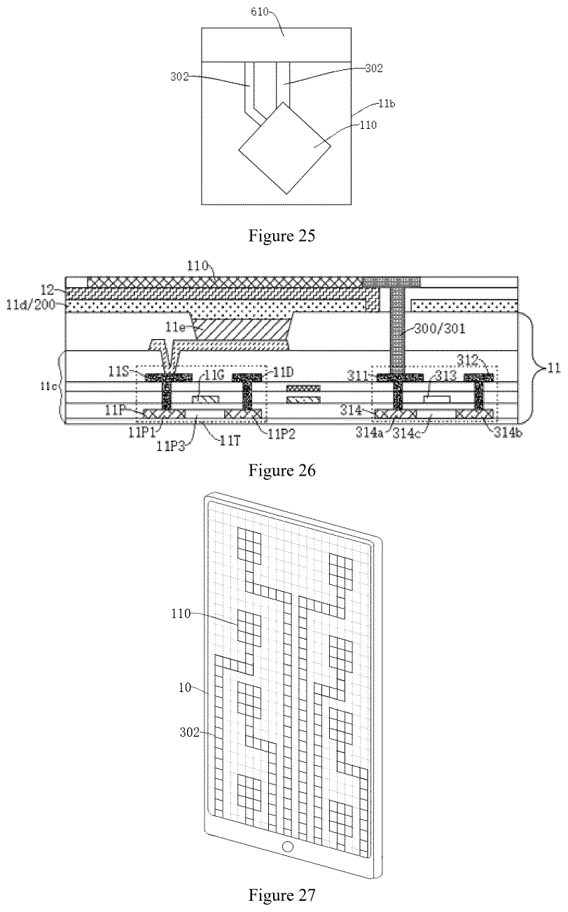

In one embodiment, when the reflecting unit 110 and/or the connection line 300 is provided in the light-transmissive conductive layer 11b, as shown in FIG. 24, the reflecting unit 110 may have one connection line 300 connected thereto (the connection line 300 is, for example, the second connection line 302); or as shown in FIG. 25, the reflecting unit 110 may have two or more connection lines 300 connected thereto (the connection line 300 is, for example, the second connection line 302).

In some embodiments, as shown in FIG. 26, the substrate 11 includes an array substrate 11c and a common electrode layer 11d. The common electrode layer 11d is located on a side of the array substrate 11c facing the display surface of the display screen 10, and the common electrode layer 11d is reused as the shielding layer 200. Enabling an original layer structure of the display screen 10 to be reused as the shielding layer 200 can simplify the structure of the display screen 10.

In one embodiment, the array substrate 11c includes a base substrate and a drive circuit provided on the base substrate. In one embodiment, a planarization layer, a pixel electrode layer, and a pixel definition layer are provided on the substrate 11. The pixel electrode layer includes a plurality of pixel electrodes distributed in an array on the planarization layer, and the pixel definition layer is located on a side of the pixel electrode layer facing away from the planarization layer. The pixel definition layer includes a pixel defining portion and a pixel opening enclosed by the pixel defining portion, and a light-emitting unit 11e may be provided in the pixel opening. The common electrode layer 11d is provided on a side of the pixel defining portion and the light-emitting unit 11e facing away from the planarization layer.

In one embodiment, an encapsulation layer 12 and a touch layer are further provided on a side of the common electrode layer 11d facing away from the pixel definition layer, and the reflecting unit 110 may be provided in the touch layer, to further simplify the structure of the display screen 10.

As shown in FIG. 26 to FIG. 33, an embodiment of a second aspect of the present application further provides a wireless communication device, including a display screen 10 according to any one of the above-described embodiments of the first aspect. Since the wireless communication device according to the present application includes the display screen 10 according to the above-described embodiment, the wireless communication device according to the embodiment of the present application has the beneficial effects of the display screen 10 according to any one of the above-described embodiments, which will not be repeated herein.

The wireless communication device in this embodiment of the present application includes, but is not limited to, devices having a display function, such as a mobile phone, a wireless wearable device, a personal digital assistant (PDA), a tablet computer, an e-book reader, a television, an access control system, a smart fixed-line telephone, a console, an electronic display board, or a display board with a transparent base substrate.

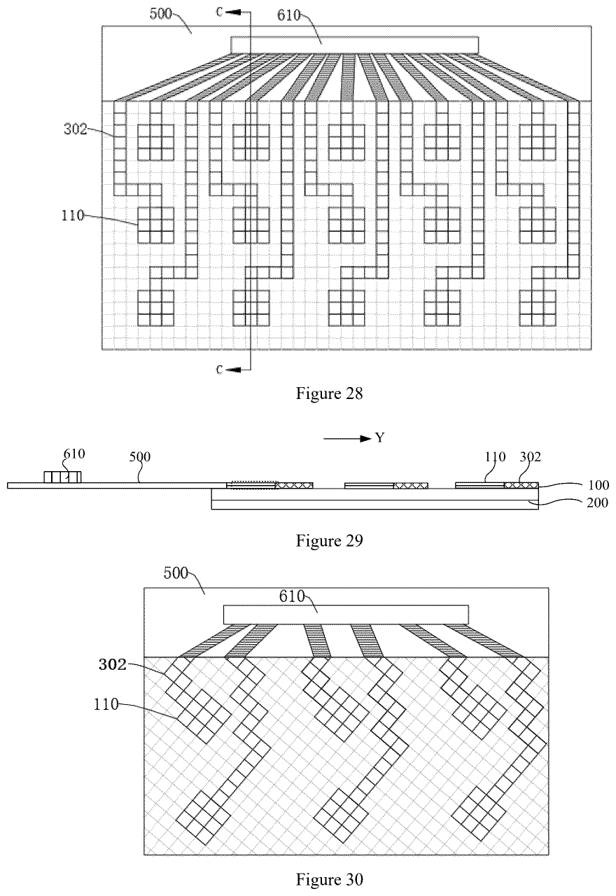

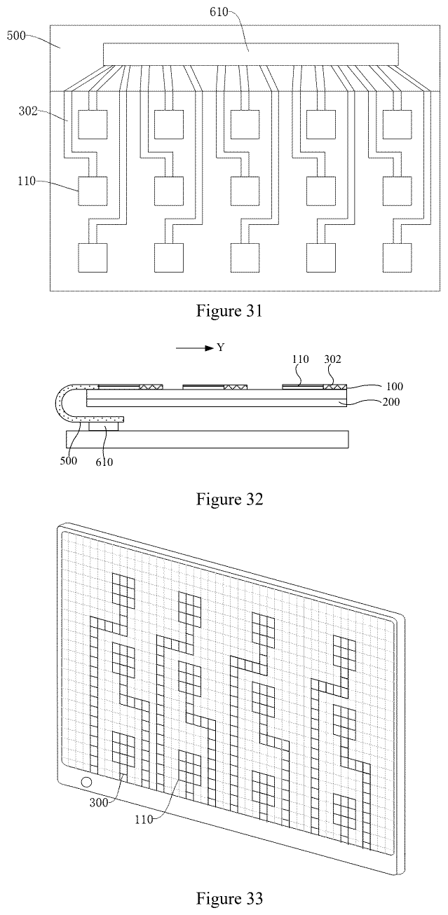

As shown in FIG. 26 to FIG. 30, the reflecting unit 110 and/or the second connection line 302 of the display screen 10 may be provided in the grid-patterned metal wiring layer. FIG. 30 differs from FIG. 28 in the extension direction of metal traces in the grid-patterned metal wiring layer. In one embodiment, as shown in FIG. 31, the reflecting unit 110 and/or the second connection line 302 of the display screen 10 may be provided in the light-transmissive conductive layer 11b.

In some embodiments, as shown in FIG. 28 and FIG. 33, the wireless communication device further includes a circuit board 500. The circuit board 500 may be a flexible circuit board. The control circuit 610 is provided on the circuit board 500, and the circuit board 500 is bent and the control circuit 610 is located on a non-display side of the display screen 10. As such, the proportion of the display area on the wireless communication device can be increased. FIG. 28 is a schematic diagram of a structure of the circuit board 500 in an unfolded state. FIG. 33 is a schematic diagram of a structure of the circuit board 500 in a folded state.

What is claimed is:

1. A display screen, comprising:
a substrate comprising a modulation circuit;
a functional layer provided on the substrate and comprising a plurality of reflecting units, wherein the reflecting unit is configured to reflect a wireless signal and is connected to the modulation circuit, and the modulation circuit is configured to adjust at least one of an amplitude and a phase of an electrical signal on the reflecting unit; and
a shielding layer provided on a side of the functional layer facing the substrate.

2. The display screen according to claim 1, wherein the modulation circuit comprises a first transistor, the first transistor comprising a first source, a first drain, a first gate, and a first semiconductor portion,
wherein one of the first source and the first drain is connected to the reflecting unit, and the other is connected to a first power signal line through the first semiconductor portion.

3. The display screen according to claim 2, further comprising a light-emitting layer located on a side of the substrate, the light-emitting layer comprising a plurality of light-emitting units, and the substrate comprising a drive circuit configured to drive the light-emitting unit to emit light,
wherein the drive circuit comprises a second transistor, the second transistor comprising a second semiconductor portion, a second gate, a second source, and a second drain, wherein the first semiconductor portion and the second semiconductor portion are provided in the same layer, or the first gate and the second gate are provided in the same layer, or the first source and the second source are provided in the same layer.

4. The display screen according to claim 2, wherein the first semiconductor portion comprises a first source region and a first drain region, the first source is electrically connected to the first source region, and the first drain is electrically connected to the first drain region; and
wherein the first drain is connected to the reflecting unit, and the first source region is connected to the first power signal line.

5. The display screen according to claim 2, wherein the first semiconductor portion comprises a first source region and a first drain region, the first source is electrically connected to the first source region, and the first drain is electrically connected to the first drain region; and
wherein the first source is connected to the reflecting unit, and the first drain region is connected to the first power signal line.

6. The display screen according to claim 2, wherein a plurality of first transistors are provided, the plurality of first transistors are sequentially connected in series with each other to form a series circuit, and the first transistor at a lead end on the series circuit is connected to the reflecting unit, and the first transistor at a tail end on the series circuit is connected to the first power signal line.

7. The display screen according to claim 6, wherein the first semiconductor portion comprises a first channel region, and first channel regions of the plurality of first transistors have different sizes from each other.

8. The display screen according to claim 6, wherein the first semiconductor portion comprises a first channel region, and first channel regions of the plurality of first transistors have different resistance values from each other.

9. The display screen according to claim 1, further comprising:
a light-emitting layer located on a side of the functional layer facing the substrate, the light-emitting layer comprising a light-emitting unit;
an encapsulation layer located on a side of the light-emitting layer facing away from the substrate and configured to encapsulate the light-emitting unit; and
a connection line, with one end of the connection line being connected to the reflecting unit, and the other end of the connection line being connected to the modulation circuit, wherein the modulation circuit is connected to the reflecting unit through the connection line,
wherein at least part of an orthographic projection of the connection line on the substrate is outside an orthographic projection of the encapsulation layer on the substrate.

10. The display screen according to claim 1, further comprising:
a light-emitting layer located on a side of the functional layer facing the substrate, the light-emitting layer comprising a light-emitting unit;
an encapsulation layer located on a side of the light-emitting layer facing away from the substrate and configured to encapsulate the light-emitting unit; and
a connection line, with one end of the connection line being connected to the reflecting unit, and the other end of the connection line being configured to be connected to a control circuit, wherein the control circuit is able to change an electrical load of the reflecting unit through the connection line,
wherein at least part of an orthographic projection of the connection line on the substrate is outside an orthographic projection of the encapsulation layer on the substrate.

11. The display screen according to claim 9, wherein the reflecting unit is located on a side of the encapsulation layer facing away from the substrate.

12. The display screen according to claim 9, wherein the connection line comprises a first connection line and a second connection line, the first connection line being configured to connect the reflecting unit and the modulation circuit, and the second connection line being configured to connect the reflecting unit and a control circuit, wherein at least part of an orthographic projection of the first connection line on the substrate and at least part of an orthographic projection of the second connection line on the substrate are outside the orthographic projection of the encapsulation layer on the substrate.

13. The display screen according to claim 9, wherein the connection line comprises a first sub-section and a second sub-section, the first sub-section connecting the reflecting unit and the second sub-section, and the second sub-section extending in a thickness direction and connecting the first sub-section to the modulation circuit or a control circuit, wherein an orthographic projection of the second sub-section on the substrate is outside the orthographic projection of the encapsulation layer on the substrate.

14. The display screen according to claim 13, wherein the first sub-section is provided in the same layer as the reflecting unit.

15. The display screen according to claim 9, wherein the encapsulation layer comprises a plurality of encapsulation portions spaced apart from each other, and an orthographic projection of each light-emitting unit on the substrate is within an orthographic projection of each encapsulation portion on the substrate.

16. The display screen according to claim 15, wherein the reflecting unit comprises a first portion and a second portion, an orthographic projection of the first portion on the substrate is within the orthographic projection of the encapsulation portion on the substrate, an orthographic projection of the second portion on the substrate is outside the orthographic projection of the encapsulation portion on the substrate, and at least part of the connection line extends in a thickness direction of the display screen and connects the second portion to the modulation circuit or control circuit.

17. A wireless communication device, comprising:
a display screen, comprising:
a substrate comprising a modulation circuit;
a functional layer provided on the substrate and comprising a plurality of reflecting units, wherein the reflecting unit is configured to reflect a wireless signal and is connected to the modulation circuit, and the modulation circuit is configured to adjust at least one of an amplitude and a phase of an electrical signal on the reflecting unit; and
a shielding layer provided on a side of the functional layer facing the substrate.
